(19) United States
(12) Patent Application Publication
(10) Pub. No.: US 2009/0294159 A1
(43) Pub. Date: Dec. 3, 2009

(54) ADVANCED PRINT CIRCUIT BOARD AND THE METHOD OF THE SAME

(76) Inventor: Kuo-Ching CHIANG, Linkou Township (TW)

Correspondence Address: Muncy, Geissler, Olds & Lowe, PLLC, P.O. BOX 1364, FAIRFAX, VA, 22038-1364, US

(21) Appl. No.: 12/132,277

(22) Filed: Jun. 3, 2008

(51) Int. Cl. H05K 1/09

(52) U.S. Cl. 174/257

(57) ABSTRACT

The present invention provides a multilayer print circuit board having at least an inner print circuit pattern and an outer print circuit pattern which are laminated on a substrate through an insulation layer and being electrically connected to each other through a blind hole provided in the insulation layer. The insulation layer is composed of a resin insoluble in an oxidization agent and inorganic powder dispersed in the resin. The inorganic powder is soluble in the oxidization agent. Wherein at least one circuit pattern is formed of non-metal material for electrically connection.

### BACKGROUND

1. Field of the Invention

The present invention relates to a print circuit board, and more particularly, to an improvement of print circuit boards having non-metal pattern.

2. Description of the Related Arts

Recently, multilayer print circuit boards used for various kinds of electronic products have been developed as the technology of high density electric circuit construction is advanced. An example of the multilayer print circuit boards includes an inner print circuit pattern provided on a surface of a substrate overlaid by an insulation layer on which an outer print circuit pattern is further provided, and the inner and outer circuit patterns are electrically connected to each other through a blind hole in the insulation layer. Electro-less plating resist layer is formed on a surface of the cured bond layer by screen-printing an ink pattern as a plating resist, it is cured by heat. Blind hole for electrically connecting inner and outer circuit patterns is formed by using a carbonic acid gas laser, and a through hole adjacent to the blind hole by drilling. An outer circuit pattern is formed on the insulation layer by the electro-less plating.

U.S. Pat. No. 6,117,706 disclosed a print circuit board. The printed circuit board comprises a substrate including a part loading portion into which an electronic part can be loaded, a plurality of contact terminals which are respectively formed on one surface of the substrate and the surfaces of which are exposed to the outside to provide external contacts, and openings respectively formed in the other surface of the substrate for insertion of bonding wires which are used to connect the electronic part, which are to be loaded into the part loading portion of the substrate, to its associated contact terminals. In the printed circuit board, each of the contact terminals is formed of a metal foil directly and closely attached to the substrate.

However, in the prior art the solution of dichromic acid/sulfuric acid/sodium fluoride is used for the chemical roughing treatment to enhance adherence of electro-less plating as mentioned in the foregoing. Dichromic acid is harmful material and the usage of the dichromic acid is prohibited in some areas. The handling of polluted mud containing the chromium (VI) is very difficult. This causes serious environmental protection problems. When sodium fluoride is used, the system for removing the fluoride contained in wastewater becomes complicated.

### SUMMARY OF THE INVENTION

An object of the present invention is to provide advanced print circuit board without the drawbacks mentioned above.

A more specific object of the present invention is to provide a multilayer print circuit board comprising: an substrate being electrically insulation and at least one circuit pattern provided on at least one of the surfaces of the substrate; the at least one circuit pattern is formed of non-metal material for electrically connection. The material of the at least one circuit pattern includes oxide containing metal, wherein the metal is one or more from Au, Zn, Ag, Pd, Pt, Rh, Ru, Cu, Fe, Ni, Co, Sn, Ti, In, Al, Ta, Ga, Ge and Sb. The circuit pattern includes Al₂O₃ doped therein. The circuit pattern is formed of carbon tube and conductive polymer. The conductive polymer includes polythiophenes, poly(selenophenes), poly(tellurophenes), polypyrroles, polyanilines.

The print circuit board includes circuit pattern including glass, conductive particles, additive. The glass is selected from Al₂O₃, B₂O₃, SiO₂, Fe₂O₃, P₂O₅, TiO₂, B₂O₃/H₃BO₃/Na₂B₄O₇, PbO, MgO, Ga₂O₃, Li₂O, V₂O₅, ZnO₂, Na₂O, ZrO₂, TlO/Tl₂O₃/TlOH, NiO/Ni, MnO₂, CuO, AgO, Sc₂O₃, SrO, BaO, CaO, Tl, ZnO and the combination thereof.

### BRIEF DESCRIPTION OF THE DRAWINGS

FIG. 1 is a sectional view showing a print circuit board of the present invention.

FIG. 2 is a sectional view showing a print circuit board of the present invention.

### DETAILED DESCRIPTION OF THE PREFERRED EMBODIMENTS

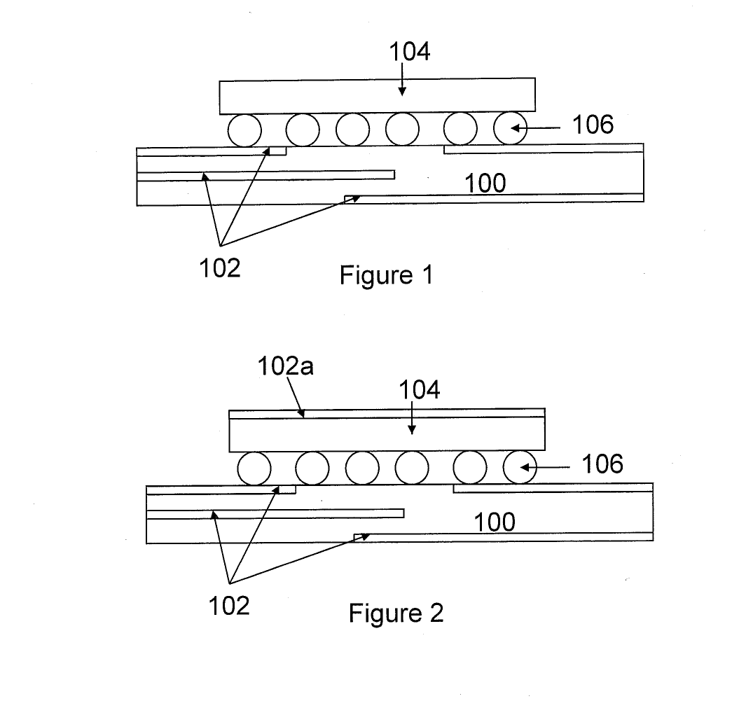

FIG. 1 is a sectional view of a print circuit board of the present invention. As shown in FIG, in the single (or multi) layer print circuit board 100 of the present invention, The PCB 100 includes an insulation substrate having a flat shape is used as a support base. The insulation substrate is made of epoxy resin or glass fiber enhanced epoxy resin. At least one circuit pattern 102 is provided on one of the upper surface or the bottom surface of the insulation substrate. The circuits may be formed within the PCB 100. The prior art includes conductive layer made of copper foils laminated on both the upper surface and the bottom surface of the insulation substrate. After dry films are exposed to an ultraviolet ray through a photomask and are developed by using a water solution of 1% sodium carbonate, they are etched by using a water solution of cupric chloride. The dry films are removed, resulting in the inner circuit pattern. The present invention do not use the conventional method due to it raises drawbacks. An electronic component or device 104 may be formed on the PCB 100 via electronic connection 106. Some of the connections 106 are coupled to the desired circuit pattern 102. The device 104 is illustrated for example only, not to limit the present invention. It should be note that any kind of device can be formed on the PCB. The shape of the connection 106 can be bump, pin and so on.

In one embodiment, the material for the conductive pattern 102 includes oxide containing metal or alloy, wherein the metal is preferable to select one or more metals from Au, Zn, Ag, Pd, Pt, Rh, Ru, Cu, Fe, Ni, Co, Sn, Ti, In, Al, Ta, Ga, Ge and Sb. Some of the transparent material includes oxide containing Zn with Al₂O₃ doped therein. This shape is constructed by using an adequate mask during the forming process of the transparent conducting layer.

The method for forming the transparent conductive layer includes ion beam method for film formation at low temperature, for example, the film can be formed with receptivity lower than 3×10⁻⁴ Ω.cm at room temperature. Further, the RF magnetron sputtered thin film method could also be used. The transparent can be higher than 82%. Under the cost and production consideration, the method for forming the antenna film, for example, indium tin oxide, could be formed at room temperature in wet atmosphere has an amorphous state, a desired pattern can be obtained at a high etching rate. After the film is formed and patterned, it is thermally treated at a temperature of about between 180 degree C. and 220 degree C. for about one hour to three hours to lower the film resistance and enhance its transmittance. Another formation is chemical solution coating method. The coating solution includes particles having an average particle diameter of 1 to 25 μm, silica particles having an average particle diameter of 1 to 25 μm, and a solvent. The weight ratio of the silica particles to the conductive particles is preferably in the range 0.1 to 1. The conductive particles are preferably metallic particles of one or more metals selected from Au, Zn, Ag, Pd, Pt, Rh, Ru, Cu, Fe, Ni, Co, Sn, Ti, In, Al, Ta, Ga, Ge and Sb. The conductive particles can be obtained by reducing a salt of one or more kinds of the aforesaid metals in an alcohol/water mixed solvent. Heat treatment is performed at a temperature of higher than about 100 degree C. The silica particles may improve the conductivity of the resulting conductive film. The metallic particles are approximately contained in amounts of 0.1 to 5% by weight in the conductive film coating liquid.

The transparent conductive film can be formed by applying the liquid on a substrate, drying it to form a transparent conductive particle layer, then applying the coating liquid for forming a transparent film onto the fine particle layer to form a transparent film on the particle layer. The coating liquid for forming a transparent conductive layer is applied onto a substrate by a method of dipping, spinning, spraying, roll coating, flexographic printing or the like and then drying the liquid at a temperature of room temperature to about 90.degree. C. After drying, the coating film is curing by heated at a temperature of not lower than 100 degree C. or irradiated with an electromagnetic wave or in the gas atmosphere.

Alternatively, the material for forming aforementioned circuits pattern includes conductive polymer (or conductive epoxy, resin), conductive carbon or conductive glue. The non-metal material is lighter weight, cost reduction, eliminates the environment issue and benefits simple process. The conventional PCB is formed of copper or the like. The cost of the copper is high and it is heavy. On the contrary, the present invention employs the non-metallic material to act the circuits pattern for PCB to save the cost and lose weight. The formation of the conductive polymer, conductive carbon or conductive glue may be shaped or formed by printing (such as screen printing), coating, attaching by adhesion or etching. The process is simplified than the conventional one. On the other hand, the thin film can be attached or formed on irregular surface or non-planner surface.

In one embodiment, the material can be formed by conductive polymer, conductive glue or conductive carbon (such as carbon nano-tube; CNT). In one embodiment, the antenna is formed of conductive carbon, such as carbon nanotubes (CNTs) that comprises multiple concentric shells and termed multi-walled carbon nanotubes (MWNTs), single-walled carbon nanotubes (SWNTs) that includes a single graphene rolled up on itself, it were synthesized in an arc-discharge process using carbon electrodes doped with transition metals. The seamless graphitic structure of single-walled carbon nanotubes (SWNTs) endows these materials with exceptional mechanical properties: Young's modulus in the low TPa range and tensile strengths in excess of 37 GPa, please refer to the Articles: Yakobson et al., Phys. Rev. Lett. 1996, 76, 2411; Lourie et al., J. Mater. Res. 1998, 13, 2418; Iijima et al., J. Chem. Phys. 1996, 104, 2089. Generally, CNT composites interpenetrating nanofiber networks, the networks comprising mutually entangled carbon nanotubes intertwined with macromolecules in a cross-linked polymer matrix. On of the method to form the CNT is the infusion of organic molecules capable of penetrating into the clumps of tangled CNTs, thereby causing the nanotube networks to expand and resulting in exfoliation. Subsequent in situ polymerization and curing of the organic molecules generates interpenetrating networks of entangled CNTs or CNT nanofibers (ropes), intertwined with cross-linked macromolecules.

The conductive polymer includes polythiophenes, poly(selenophenes), poly(tellurophenes), polypyrroles, polyanilines. In one embodiment, the conductive polymer maybe made from at least one precursor monomer selected from thiophenes, selenophenes, tellurophenes, pyrroles, anilines, and polycyclic aromatics. The polymers made from these monomers are referred to herein as polythiophenes, poly(selenophenes), poly(tellurophenes), polypyrroles, polyanilines, and polycyclic aromatic polymers, respectively. US. Patent Application 20080017852 to Huh; Dal Ho et al., entitled “Conductive Polymer Composition Comprising Organic Ionic Salt and Optoelectronic Device Using the Same”, it discloses a method of forming conductive polymer. In one embodiment, the conductive polymer is an organic polymer semiconductor, or an organic semiconductor. The conductive polyacetylenes type include polyacetylene itself as well as polypyrrole, polyaniline, and their derivatives. Conductive organic polymers often have extended delocalized bonds, these create a band structure similar to silicon, but with localized states. The zero-band gap conductive polymers may behave like metals.

Alternatively, the circuits pattern of PCB can be formed of conductive glue that can be made of material such as silicon glue or epoxy, etc. The thin film antenna is transparent. In one embodiment, the conductive glue may be formed of the mixture of at least one glass, additive and conductive particles (such as metallic particles). The conductive glue maybe includes aluminum (and/or silver) powder and a curing agent. The glass is selected from Al₂O₃, B₂O₃, SiO₂, Fe₂O₃, P₂O₅, TiO₂, B₂O₃/H₃BO₃/Na₂B₄O₇, PbO, MgO, Ga₂O₃, Li₂O, V₂O₅, ZnO₂, Na₂O, ZrO₂, TlO/Tl₂O₃/TlOH, NiO/Ni, MnO₂, CuO, AgO, Sc₂O₃, SrO, BaO, CaO, Tl, ZnO. The additive material includes oleic acid.

Alternatively, the connection 106 of electronic device 104 may be formed of above material to avoid the environment issue. The material has no lead contained therein. Therefore, the lead-free structure can be provided. Further, the aforementioned conductive material 102a for circuit pattern can be formed on at least one surface of the device 104, for example upper surface, side surface, lower surface to enhance the thermal dissipation as shown in FIG. 2.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A print circuit board comprising:
a substrate;
at least one circuit pattern provided on at least one surface of the substrate;
wherein said at least one circuit pattern is formed of non-metal material for electrically connection.

2. The print circuit board of claim 1, wherein the material of said at least one circuit pattern includes oxide containing metal, wherein said metal is one or more from Au, Zn, Ag, Pd, Pt, Rh, Ru, Cu, Fe, Ni, Co, Sn, Ti, In, Al, Ta, Ga, Ge and Sb.

3. The print circuit board of claim 2, wherein said transparent antenna includes Al₂O₃ doped therein.

4. The print circuit board of claim 1, wherein said circuit pattern is formed of carbon tube.

5. The print circuit board of claim 1, wherein said circuit pattern is formed of conductive polymer, epoxy or resin.

6. The print circuit board of claim 5, wherein said conductive polymer includes polythiophenes, poly(selenophenes), poly(tellurophenes), polypyrroles, polyanilines.

7. The print circuit board of claim 1, wherein said circuit pattern includes conductive glue including glass, conductive particles, additive.

8. The print circuit board of claim 7, wherein the glass is selected from Al₂O₃, B₂O₃, SiO₂, Fe₂O₃, P₂O₅, TiO₂, B₂O₃/H₃BO₃/Na₂B₄O₇, PbO, MgO, Ga₂O₃, Li₂O, V₂O₅, ZnO₂, Na₂O, ZrO₂, TlO/Tl₂O₃/TlOH, NiO/Ni, MnO₂, CuO, AgO, Sc₂O₃, SrO, BaO, CaO, Tl, ZnO and the combination thereof.

9. The print circuit board of claim 1, an electronic component is connected to said at least one circuits pattern, wherein said electronic component includes connection formed of said non-metal material.

10. The print circuit board of claim 9, wherein non-metal material includes oxide containing metal, wherein said metal is one or more from Au, Zn, Ag, Pd, Pt, Rh, Ru, Cu, Fe, Ni, Co, Sn, Ti, In, Al, Ta, Ga, Ge and Sb.

11. The print circuit board of claim 10, wherein said non-metal material is formed of carbon tube.

12. The print circuit board of claim 9, wherein said non-metal material is formed of conductive polymer, epoxy or resin.

13. The print circuit board of claim 12, wherein said conductive polymer includes polythiophenes, poly(selenophenes), poly(tellurophenes), polypyrroles, polyanilines.

14. The print circuit board of claim 9, wherein said non-metal material includes conductive glue including glass, conductive particles, additive.

15. The print circuit board of claim 14, wherein the glass is selected from Al₂O₃, B₂O₃, SiO₂, Fe₂O₃, P₂O₅, TiO₂, B₂O₃/H₃BO₃/Na₂B₄O₇, PbO, MgO, Ga₂O₃, Li₂O, V₂O₅, ZnO₂, Na₂O, ZrO₂, TlO/Tl₂O₃/TlOH, NiO/Ni, MnO₂, CuO, AgO, Sc₂O₃, SrO, BaO, CaO, Tl, ZnO and the combination thereof.

16. The print circuit board of claim 1, an electronic component is connected to said at least one circuits pattern, wherein said electronic component includes a layer formed on a surface of said electronic component, wherein said layer is formed by said non-metal material.

17. The print circuit board of claim 16, wherein non-metal material includes oxide containing metal, wherein said metal is one or more from Au, Zn, Ag, Pd, Pt, Rh, Ru, Cu, Fe, Ni, Co, Sn, Ti, In, Al, Ta, Ga, Ge and Sb.

18. The print circuit board of claim 16, wherein said non-metal material is formed of carbon tube.

19. The print circuit board of claim 16, wherein said non-metal material is formed of conductive polymer, epoxy or resin.

20. The print circuit board of claim 1, wherein said non-metal material includes conductive glue including glass, conductive particles, additive.
